(19) United States
(12) Patent Application Publication
(10) Pub. No.: US 2024/0349612 A1
(43) Pub. Date: Oct. 17, 2024

(54) PIEZOELECTRIC SENSOR AND TACTILE FEEDBACK DEVICE

(71) Applicants: Beijing BOE Technology Development Co., Ltd., Beijing (CN); BOE Technology Group Co., Ltd., Beijing (CN)

(72) Inventors: Yuju CHEN, Beijing (CN); Hui HUA, Beijing (CN)

(21) Appl. No.: 18/292,277

(22) PCT Filed: Jul. 1, 2022
(86) PCT No.: PCT/CN2022/103401

§ 371 Date: Jan. 25, 2024

(30) Foreign Application Priority Data
Jul. 28, 2021 (CN) 202110857000.3

(51) Int. Cl. H10N 30/30; G06F 3/01; H10N 30/85; H10N 30/87

(52) U.S. Cl. CPC H10N 30/302; G06F 3/016; H10N 30/85; H10N 30/872

(57) ABSTRACT

Embodiments of the present disclosure provide a piezoelectric sensor and a tactile feedback device. The piezoelectric sensor includes: a base substrate, and a first electrode layer, a first blocking layer, a piezoelectric material layer and a second electrode layer that are successively stacked on the base substrate, wherein the first electrode layer is close to the base substrate, and the first blocking layer is used for blocking the diffusion of ions of the piezoelectric material layer to the first electrode layer.

### CROSS-REFERENCE TO RELATED APPLICATIONS

The present application claims priority to Chinese Patent Application No. 202110857000.3, entitled “Piezoelectric Sensor and Tactile Feedback Device”, filed to the China National Intellectual Property Administration on Jul. 28, 2021, the entire content of which is incorporated herein by reference.

### TECHNICAL FIELD

The present disclosure relates to the technical field of sensors, in particular to a piezoelectric sensor and a haptic apparatus.

### BACKGROUND

Haptics is the focus of today's technology development, and specifically, haptics enables a terminal to interact with a human body through the sense of touch. Haptics may further be divided into two types, one is vibration feedback, and the other is a tactile sense representation technology.

A surface tactile sense representation technology enables a naked finger to sense properties of an object by touching a screen, realizes efficient and natural interaction at a multimedia terminal, and has a huge research value, thereby obtaining extensive attention of domestic and foreign researchers. In terms of a physical meaning of the surface tactile sense, a surface roughness of an object interacts with a surface of the skin (fingertip), resulting in different friction due to different surface structures. By controlling the surface friction, simulations of different tactile senses/tactile impressions may be realized.

### SUMMARY

An embodiment of the present disclosure provides a piezoelectric sensor and a haptic apparatus. The piezoelectric sensor includes a base substrate, and a first electrode layer, a first blocking layer, a piezoelectric material layer and a second electrode layer that are successively stacked on the base substrate, wherein the first electrode layer is close to the base substrate, and the first blocking layer is configured to block diffusion of ions of the piezoelectric material layer to the first electrode layer.

In a possible implementation, in the piezoelectric sensor provided by the embodiment of the present disclosure, a material of the first blocking layer is Ti.

In a possible implementation, in the piezoelectric sensor provided by the embodiment of the present disclosure, a thickness of the first blocking layer is less than 10 nm.

In a possible implementation, in the piezoelectric sensor provided by the embodiment of the present disclosure, a transmittance of the first blocking layer is greater than or equal to 60%.

In a possible implementation, the piezoelectric sensor provided by the embodiment of the present disclosure further includes a second blocking layer located between the first blocking layer and the piezoelectric material layer, a material of the second blocking layer is different from a material of the first blocking layer, and the second blocking layer is configured to block diffusion of ions of the piezoelectric material layer to the first electrode layer.

In a possible implementation, in the piezoelectric sensor provided by the embodiment of the present disclosure, a material of the second blocking layer is HfO₂ or LiNbO₃.

In a possible implementation, in the piezoelectric sensor provided by the embodiment of the present disclosure, a thickness of the second blocking layer is less than 50 nm.

In a possible implementation, the piezoelectric sensor provided by the embodiment of the present disclosure further includes an insulating layer located on one side of the second electrode layer facing away from the base substrate, and a wiring layer located on one side of the insulating layer facing away from the base substrate; the wiring layer is electrically connected with the second electrode layer by a via hole penetrating through the insulating layer; and the first electrode layer is grounded, and the wiring layer is connected to a driving signal end.

In a possible implementation, in the piezoelectric sensor provided by the embodiment of the present disclosure, a material of the insulating layer is SiO₂ or photoresist.

In a possible implementation, in the piezoelectric sensor provided by the embodiment of the present disclosure, materials of the first electrode layer and the second electrode layer are transparent conductive materials, and a material of the wiring layer is Ti/Ni/Au or Ti/Al/Ti.

In a possible implementation, in the piezoelectric sensor provided by the embodiment of the present disclosure, a thickness of the piezoelectric material layer ranges from 500 nm to 2000 nm.

In a possible implementation, in the piezoelectric sensor provided by the embodiment of the present disclosure, the piezoelectric material layer includes at least one of lead zirconate titanate, aluminum nitride, zinc oxide, barium titanate, lead titanate, potassium niobate, lithium niobate, lithium tantalate, or gallium lanthanum silicate.

Correspondingly, an embodiment of the present disclosure further provides a haptic apparatus, including any one of the above piezoelectric sensor.

### BRIEF DESCRIPTION OF FIGURES

FIG. 1 is a schematic structural diagram of a piezoelectric sensor provided by an embodiment of the present disclosure.

FIG. 2 is a transmittance of a first blocking layer.

FIG. 3 is a schematic diagram of resistance changes of a first electrode layer before and after annealing when a first blocking layer is arranged and when the first blocking layer is not arranged.

FIG. 4 is a schematic structural diagram of another piezoelectric sensor provided by an embodiment of the present disclosure.

FIG. 5 is a schematic diagram of XRD of HfO₂ measured by the present disclosure and a schematic diagram of standard XRD of HfO₂

FIG. 6 is a schematic structural diagram of another piezoelectric sensor provided by an embodiment of the present disclosure.

### DETAILED DESCRIPTION

In order to make objectives, technical solutions and advantages of embodiments of the present disclosure clearer, the technical solutions of the embodiments of the present disclosure will be clearly and completely described below with reference to accompanying drawings of the embodiments of the present disclosure. Apparently, the described embodiments are some, but not all, embodiments of the present disclosure. The embodiments of the present disclosure and features in the embodiments may be mutually combined without conflicting. Based on the described embodiments of the present disclosure, all other embodiments obtained by those of ordinary skill in the art without creative work shall fall within the protection scope of the present disclosure.

Unless otherwise defined, technical terms or scientific terms used in the present disclosure should have the ordinary meaning as understood by those of ordinary skill in the art to which the present disclosure pertains. “Include” or “comprise” and similar words used in the present disclosure mean that the elements or objects appearing before the words cover the elements or objects recited after the words and their equivalents, but do not exclude other elements or objects. The words “connect” or “link” or the like are not limited to physical or mechanical connection, but may include electrical connection, whether direct or indirect. “Inner”, “outer”, “up”, “down” and the like are only used for representing a relative position relationship, and after an absolute position of a described object is changed, the relative position relationship may also be changed accordingly.

It needs to be noted that sizes and shapes of figures in the accompanying drawings do not reflect a true scale, and are only intended to illustrate contents of the present disclosure. In addition, identical or similar labels throughout indicate identical or similar components or components with identical or similar functions.

A thin-film piezoelectric material has characteristics of high dielectric constant and transparency, and is quite suitable for a screen-integrated vibrator structure. Lead zirconate titanate piezoelectric ceramics are more frequently applied at present due to an excellent piezoelectric property. There are many process methods for manufacturing a PZT film layer, including a dry method coating film (sputter) and a wet method coating film (sol-gel). If good piezoelectric constant characteristics need to be realized, a PZT material needs to be subjected to a high-temperature annealing process, and the process needs to perform PZT grain growth at a 550° C.-650° C. air environment to form a good solid solution phase. When a vibrator structure is integrated into a display device, in order not to affect a display quality of the display device, the vibrator structure needs to use a transparent electrode (such as ITO) as a base electrode and a growth layer. However, there are problems as follows: on the one hand, because the ITO is mainly conductive through oxygen vacancy but the PZT is a perovskite phase and needs enough grain sizes to form the piezoelectric property, the PZT needs to be subjected to high-temperature oxygen annealing; and an annealing process will result in a greatly increased ITO resistance value, an increased line resistance, and an reduced electrical conductivity, which is not conductive to high-frequency driving of the device. In addition, because Pb ions in the PZT have small ion radii and are extremely prone to diffusing among oxides, once a PZT thin film is directly manufactured on the ITO, under annealing processes at different temperatures, it is verified by the inventor of the present disclosure that all the Pb ions are diffused by about 100 nm; and the diffusion not only leads to rising of the ITO resistance, but also leads to loss of the Pb ions in the PZT film layer, causing a perovskite phase state being converted to a Pyrochlore phase state, reducing the piezoelectric property of the PZT, and thereby reducing the property of the piezoelectric device.

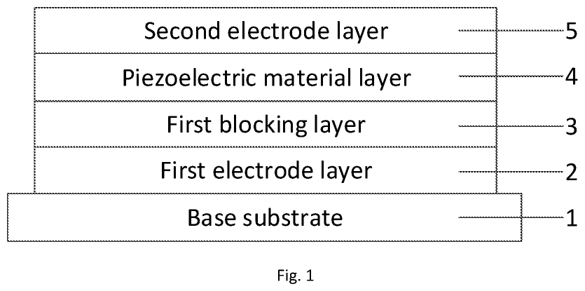

In view of this, an embodiment of the present disclosure provides a piezoelectric sensor, as shown in FIG. 1, including: a base substrate 1, and a first electrode layer 2, a first blocking layer 3, a piezoelectric material layer 4 and a second electrode layer 5 that are successively stacked on the base substrate 1, wherein the first electrode layer 2 is close to the base substrate 1, and the first blocking layer 3 is configured to block diffusion of ions of the piezoelectric material layer 4 to the first electrode layer 2.

According to the above piezoelectric sensor provided by the embodiment of the present disclosure, since the piezoelectric material layer 4 (such as PZT) may be formed by adopting a dry method coating film or a wet method coating film, to realize good piezoelectric constant characteristics, a PZT material needs to be subjected to a high-temperature annealing process, and the process needs to perform PZT grain growth at a 550° C.-650° C. air environment to form a good solid solution phase. Because the first electrode layer 2 (such as the ITO) is mainly conductive through oxygen vacancy, in the high-temperature annealing process, oxygen in the PZT will be diffused to an oxygen vacancy position of the ITO, resulting in rising of an ITO resistance (descending of an electrical conductivity), which is not conductive to high-frequency driving of a device; and in addition, Pb ions are smaller in radius, the Pb ions are extremely prone to diffusing among oxides, the diffusion not only leads to rising of the ITO resistance, but also leads to the loss of the Pb ions in the PZT film layer, causing a phase state being converted to a Pyrochlore phase state, and thereby reducing a piezoelectric property of the PZT. According to the embodiment of the present disclosure, by arranging the first blocking layer 3 between the piezoelectric material layer 4 and the first electrode 2, the first blocking layer 3 may block ions (such as O and Pb) of the piezoelectric material layer 4 from diffusing to the first electrode 2, so that when the piezoelectric material layer 4 is subjected to high-temperature oxygen annealing, the electrical conductivity of the ITO may be maintained; and meanwhile, the Pb is prevented from diffusing into the ITO, a PZT perovskite crystal phase is easy to maintain, and the piezoelectric property of the piezoelectric material layer 4 is improved.

In a specific implementation process, the base substrate 1 may be a substrate made of glass, or a substrate made of silicon or SiO₂, or a substrate made of sapphire, or a substrate made of metal wafers, which is not limited here, and those skilled in the art may set the base substrate 1 according to actual application needs.

In specific implementation, materials of the first electrode layer 2 and the second electrode layer 5 are transparent conductive materials, for example, indium tin oxide (ITO), zinc indium oxide (IZO), etc. Those skilled in the art may set the materials of the first electrode layer 2 and the second electrode layer 5 according to actual application needs, which is not limited here.

In specific implementation, the piezoelectric material layer 4 is not limited to lead zirconate titanate (Pb(Zr,Ti)O₃, PZT), and may further be at least one of aluminium nitride (AlN), zinc oxide (ZnO), barium titanate (BaTiO₃), lead titanate (PbTiO₃), potassium niobate (KNbO₃), lithium niobate (LiNbO₃), lithium tantalate (LiTaO₃), and gallium lanthanum silicate (La₃Ga₅SiO₁₄). Thus, the piezoelectric sensor is transparent while a vibration performance of the piezoelectric sensor is ensured. Materials for manufacturing the piezoelectric material layer 4 may be selected specifically according to the actual application needs of those skilled in the art, which is not limited here. When the PZT is used to manufacture the piezoelectric material layer 4, since the PZT has a high piezoelectric coefficient, the piezoelectric property of the piezoelectric sensor is ensured, and the corresponding piezoelectric sensor may be applied to a haptic device; and because the PZT has high transmission of light, when the PZT is integrated to a display device, a display quality of the display device is not affected.

In specific implementation, in the above piezoelectric sensor provided by the embodiment of the present disclosure, a material of the first blocking layer may be Ti, because a property of Ti is stable, Ti is a metal which is not prone to oxidation at high temperature, and the formed first blocking layer has a relatively small thinness.

In specific implementation, in order to ensure the transparency of the piezoelectric sensor, in the above piezoelectric sensor provided by the embodiment of the present disclosure, the thickness of the first blocking layer is less than 10 nm. For example, it may be 9 nm, 8 nm, 7 nm, 6 nm, 5 nm, 4 nm, etc., and the embodiment of the present disclosure takes 5 nm as an example.

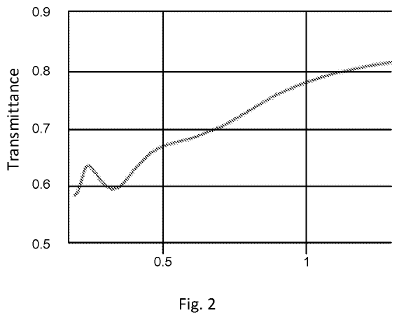

In specific implementation, in the above piezoelectric sensor provided by the embodiment of the present disclosure, as shown in FIG. 2, a transmittance of the first blocking layer is greater than or equal to 60%. For example, it may be 60%, 70%, 80%, 90%, etc. In this way, when the piezoelectric sensor of the present disclosure is integrated into the display device, the display quality of the display device is not affected.

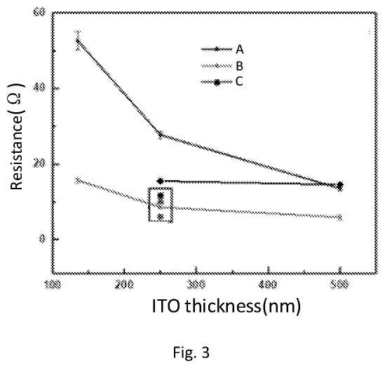

According to the piezoelectric sensor provided by the embodiment of the present disclosure, by adopting Ti to manufacture the first blocking layer between the first electrode layer and the piezoelectric material layer, after subjecting the piezoelectric material layer to the high-temperature annealing process, the inventor of the present disclosure detects a electrical conductivity of the first electrode layer. According to actual measurement in an experiment, as shown in FIG. 3, a curve A is a resistance change of the first electrode layer after film formation without the first blocking layer, a curve B is a resistance change of the first electrode layer after film formation and annealing at 250° C. without the first blocking layer, and a curve C is a resistance change of the first electrode layer after film formation of the piezoelectric material layer 4 and annealing at 500° C. without the first blocking layer. A black block, a black triangle and a black circle in a small black box are respectively the resistance change of the first electrode layer after film formation, the resistance change of the first electrode layer after film formation and annealing at 250° C., and the resistance change of the first electrode layer after film formation of the piezoelectric material layer 4 and annealing at 500° C. when the first blocking layer is arranged by the present disclosure. It can be seen that when the first blocking layer is not arranged, the resistance change of the first electrode layer before and after annealing is relatively obvious, and when the first blocking layer is arranged, a resistance change tendency of the first electrode layer before and after annealing is small. Therefore, after adding the first blocking layer on a surface of the first electrode layer, through high-temperature annealing, a resistance value is not changed obviously, and no loss of the electrical conductivity is caused.

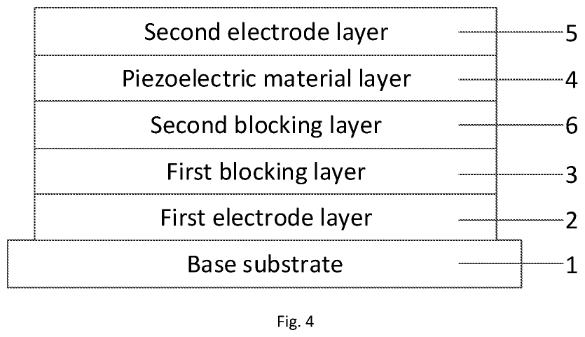

In specific implementation, although the first blocking layer 3 manufactured by adopting Ti may block most ions in the PZT from diffusing into the first electrode layer 2, in order to further improve the electrical conductivity of the first electrode layer and the piezoelectric property of the piezoelectric material layer 4, the above piezoelectric sensor provided by the embodiment of the present disclosure, as shown in FIG. 4, further includes a second blocking layer 6 located between the first blocking layer 3 and the piezoelectric material layer 4. A material of the second blocking layer 6 is different from the material of the first blocking layer 3, and the second blocking layer 6 is configured to further block the diffusion of ions of the piezoelectric material layer 4 to the first electrode layer 2.

In specific implementation, in the above piezoelectric sensor provided by the embodiment of the present disclosure, the material of the second blocking layer may be HfO₂ or LiNbO₃.

Specifically, when the material of the second blocking layer is HfO₂, HfO₂ may serve as a seed layer. When a thin film grows, the seed layer is needed for orientation, so that when the piezoelectric material layer is manufactured on the second blocking layer, a grown crystal orientation of the piezoelectric material layer will be related to the orientation of the second blocking layer, which is conductive to the grown crystal orientation of the piezoelectric material layer, thereby increasing the piezoelectric property of the piezoelectric material layer. A schematic diagram of XRD of HfO₂ being deposited on the first electrode layer is shown in FIG. 5, a bottom XRD diagram is a schematic diagram of a standard XRD of HfO₂, an upper XRD diagram is a schematic diagram of XRD of HfO₂ measured by the embodiment of the present disclosure, and it can be seen that crystalline phases of the two are approachable.

Specifically, when the material of the second blocking layer is LiNbO₃ (LNO for short), LiNbO₃ may also serve as a seed layer. Since LiNbO₃ itself is conductive, compared with HfO₂, LiNbO₃ may further improve the electrical conductivity while avoiding the diffusion of Pb and O.

When the dry method or wet method process is adopted for manufacturing the piezoelectric material layer (such as PZT), there are more or less micropores in the process. Once there is a hole in the PZT, the first electrode layer is connected with the second electrode layer to form a short circuit. Since the LNO is a conductor, HfO₂ is used as a second blocking layer, compared with the LNO as the second blocking layer, an insulativity of HfO₂ is more resisted when the hole is generated in the PZT layer, and the problem of short circuit of the first electrode layer and the second electrode layer is avoided.

Therefore, HfO₂ or LiNbO₃ may be selected to serve as the second blocking layer according to actual requirements.

In specific implementation, in the above piezoelectric sensor provided by the embodiment of the present disclosure, a thickness of the second blocking layer is less than 50 nm, for example, 40 nm, 30 nm, 20 nm, and 10 nm.

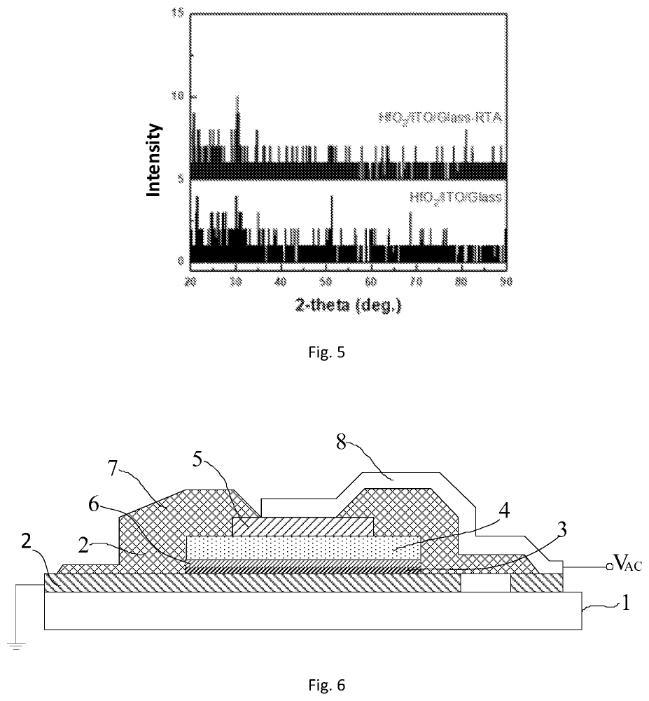

In specific implementation, the above piezoelectric sensor provided by the embodiment of the present disclosure, as shown in FIG. 6, further includes an insulating layer 7 located on one side of the second electrode layer 5 facing away from the base substrate 1, and a wiring layer 8 located on one side of the insulating layer 7 facing away from the base substrate 1; the wiring layer 8 is electrically connected with the second electrode layer 5 by a via hole penetrating through the insulating layer 7.

The first electrode layer 2 is grounded, and the wiring layer 8 is connected to a driving signal end. In specific implementation, the first electrode layer 2 is grounded by an inverse piezoelectric effect, and by loading a high-frequency alternating voltage signal (V_{AC}) to the second electrode layer 5, application of a high-frequency alternating voltage signal on the e piezoelectric material layer 4 is realized, so that high-frequency vibration is generated; and laser may be adopted for measuring vibration displacement, so that a using performance of the piezoelectric sensor is ensured. A material of the insulating layer 7 may be SiO₂, photoresist (SOC-5004U) or silicon nitride (Si₃N₄), etc., which is not limited herein. Of course, in addition to the various film layers mentioned above, other film layers may further be arranged in the above piezoelectric sensor provided by the embodiment of the present disclosure according to practical application.

In specific implementation, in the above piezoelectric sensor provided by the embodiment of the present disclosure, the thickness of the first electrode layer and the second electrode layer may range from 250 nm to 500 nm, a material of the wiring layer is Ti/Ni/Au, Ti may be 10 nm, Ni may be 100 nm, and Au may be 20 nm; or the material of the wiring layer is Ti/Al/Ti, Ti may be 10 nm, and Al may be 100 nm.

In specific implementation, in the above piezoelectric sensor provided by the embodiment of the present disclosure, a thickness of the piezoelectric material layer may range from 500 nm to 2000 nm. For example, the thickness of the piezoelectric material layer may be 500 nm, 1000 nm, or 2000 nm. In practical application, the thickness of the piezoelectric material layer may be set as close to zero as possible, and a thin design of the piezoelectric sensor is considered while good vibration characteristics of piezoelectric materials are ensured.

The piezoelectric sensor provided by the embodiment of the present disclosure may be applied to fields such as medical treatment, automotive electronics, and exercise trace systems, is particularly suitable for the field of wearable devices, monitoring and treatment use outside or implanted in the human body, or may be applied to fields such as artificial intelligence electronic skin. Specifically, the piezoelectric sensor may be applied to a brake pad, a keyboard, a mobile terminal, a gamepad, a vehicle and other devices generating vibration and mechanical properties.

Based on the same inventive concept, an embodiment of the present disclosure further provides a haptic apparatus, including the above piezoelectric sensor provided by the embodiment of the present disclosure. A problem solving principle of the haptic apparatus is similar to that of the above piezoelectric sensor, so for implementation of the haptic apparatus, reference may be made to implementation of the above piezoelectric sensor, and repetition is omitted.

In specific implementation, the haptic apparatus may be integrated with a touch screen, a position of human body touch may be determined through the touch screen, so that a corresponding vibration waveform, amplitude and frequency are generated, and human-computer interaction may be realized. For another example, the haptic apparatus may further be reused as a piezoelectric body, the position of human body touch may be determined through the piezoelectric sensor, so that a corresponding vibration waveform, amplitude and frequency are generated, and human-computer interaction may be realized. Certainly, the haptic apparatus may further be applied to fields such as medical treatment, automotive electronics, and exercise trace systems, which is not described in detail.

According to the piezoelectric sensor and the haptic apparatus provided by the embodiments of the present disclosure, the piezoelectric material layer (such as PZT) may be formed by adopting the dry method coating film or wet method coating film, to realize the good piezoelectric constant characteristics, the PZT material need to be subjected to the high-temperature annealing process, and the process needs to perform PZT grain growth at a 550° C.-650° C. air environment to form the good solid solution phase. Because the first electrode layer (such as the ITO) is mainly conductive through oxygen vacancy, in the high-temperature annealing process, oxygen in the PZT will be diffused to an oxygen vacancy position of the ITO, resulting in rising of the ITO resistance (descending of an electrical conductivity), which is not conductive to high-frequency driving of the device; and in addition, the Pb ions are smaller in radius, the Pb ions are extremely prone to diffusing among oxides, the diffusion not only leads to rising of the ITO resistance, but also leads to the loss of the Pb ions in the PZT film layer, causing a phase state being converted to a Pyrochlore phase state, and thereby reducing the piezoelectric property of the PZT. According to the embodiment of the present disclosure, by arranging the first blocking layer between the piezoelectric material layer and the first electrode, the first blocking layer may block ions (such as O and Pb) of the piezoelectric material layer from diffusing to the first electrode, so that when the piezoelectric material layer is subjected to high-temperature oxygen annealing, the electrical conductivity of the ITO may be maintained; and meanwhile, the Pb is prevented from diffusing into the ITO, a PZT perovskite crystal phase is easy to maintain, and the piezoelectric property of the piezoelectric material layer is improved.

Although the preferred embodiments of the present disclosure have been described, those skilled in the art can make additional changes and modifications on these embodiments once they know the basic creative concept. So the appended claims are intended to include the preferred embodiments and all changes and modifications that fall into the scope of the present disclosure.

Apparently, those skilled in the art may perform various changes and modifications on the embodiments of the present disclosure without departing from the spirit and scope of the embodiments of the present disclosure. In this way, if these changes and modifications on the embodiments of the present disclosure fall in the scope of the claims of the present disclosure and their equivalent technologies, the present disclosure is intended to include these changes and modification.

1. A piezoelectric sensor, comprising: a base substrate, and a first electrode layer, a first blocking layer, a piezoelectric material layer and a second electrode layer that are successively stacked on the base substrate, wherein the first electrode layer is close to the base substrate, and the first blocking layer is configured to block diffusion of ions of the piezoelectric material layer to the first electrode layer.

2. The piezoelectric sensor according to claim 1, wherein a material of the first blocking layer is Ti.

3. The piezoelectric sensor according to claim 1, wherein a thickness of the first blocking layer is less than 10 nm.

4. The piezoelectric sensor according to claim 1, wherein a transmittance of the first blocking layer is greater than or equal to 60%.

5. The piezoelectric sensor according to claim 1, further comprising a second blocking layer located between the first blocking layer and the piezoelectric material layer, a material of the second blocking layer being different from a material of the first blocking layer, and the second blocking layer being configured to block diffusion of ions of the piezoelectric material layer to the first electrode layer.

6. The piezoelectric sensor according to claim 5, wherein the material of the second blocking layer is HfO₂ or LiNbO₃.

7. The piezoelectric sensor according to claim 5, wherein a thickness of the second blocking layer is less than 50 nm.

8. The piezoelectric sensor according to claim 1, further comprising an insulating layer located on one side facing away from the base substrate, of the second electrode layer, and a wiring layer located on one side facing away from the base substrate, of the insulating layer, wherein the wiring layer is electrically connected with the second electrode layer by a via hole penetrating through the insulating layer; and
the first electrode layer is grounded, and the wiring layer is connected to a driving signal end.

9. The piezoelectric sensor according to claim 8, wherein a material of the insulating layer is SiO₂ or photoresist.

10. The piezoelectric sensor according to claim 8, wherein materials of the first electrode layer and the second electrode layer are transparent conductive materials, and a material of the wiring layer is Ti/Ni/Au or Ti/Al/Ti.

11. The piezoelectric sensor according to claim 1, wherein a thickness of the piezoelectric material layer ranges from 500 nm to 2000 nm.

12. The piezoelectric sensor according to claim 1, wherein the piezoelectric material layer comprises at least one of lead zirconate titanate, aluminum nitride, zinc oxide, barium titanate, lead titanate, potassium niobate, lithium niobate, lithium tantalate, or gallium lanthanum silicate.

13. A haptic apparatus, comprising a piezoelectric sensor, wherein the piezoelectric sensor comprises a base substrate, and a first electrode layer, a first blocking layer, a piezoelectric material layer and a second electrode layer that are successively stacked on the base substrate, wherein the first electrode layer is close to the base substrate, and the first blocking layer is configured to block diffusion of ions of the piezoelectric material layer to the first electrode layer.

14. The haptic apparatus according to claim 13, wherein a material of the first blocking layer is Ti.

15. The haptic apparatus according to claim 13, wherein a thickness of the first blocking layer is less than 10 nm.

16. The haptic apparatus according to claim 13, wherein a transmittance of the first blocking layer is greater than or equal to 60%.

17. The haptic apparatus according to claim 13, wherein the piezoelectric sensor further comprises a second blocking layer located between the first blocking layer and the piezoelectric material layer, a material of the second blocking layer being different from a material of the first blocking layer, and the second blocking layer being configured to block diffusion of ions of the piezoelectric material layer to the first electrode layer.

18. The haptic apparatus according to claim 17, wherein the material of the second blocking layer is HfO₂ or LiNbO₃.

19. The haptic apparatus according to claim 17, wherein a thickness of the second blocking layer is less than 50 nm.

20. The haptic apparatus according to any one of claim 13, wherein the piezoelectric sensor further comprises an insulating layer located on one side facing away from the base substrate, of the second electrode layer, and a wiring layer located on one side facing away from the base substrate, of the insulating layer, wherein the wiring layer is electrically connected with the second electrode layer by a via hole penetrating through the insulating layer; and
the first electrode layer is grounded, and the wiring layer is connected to a driving signal end.
